(19) United States
(12) Patent Application Publication
(10) Pub. No.: US 2008/0305278 A1
(43) Pub. Date: Dec. 11, 2008

(54) Glass coating of polymers

(76) Inventors: Stephen C. Jacobsen, Salt Lake City, UT (US); David Marceau, Salt Lake City, UT (US)

Correspondence Address: THORPE NORTH & WESTERN, LLP., P.O. Box 1219, SANDY, UT, 84091-1219, US

(21) Appl. No.: 11/810,703

(22) Filed: Jun. 5, 2007

(51) Int. Cl. C23C 14/28; B05D 3/10; C23C 16/00

(52) U.S. Cl. 427/595; 427/255.37; 427/344

(57) ABSTRACT

A method for modifying a plastic surface is disclosed. The method can include chemically reacting a polysilicone compound placed in contact with the plastic surface to form a silicon dioxide glass layer on the surface portion. The glass layer can be modified in a second process to create a desired surface property.

### FIELD OF THE INVENTION

The present invention relates to glass coating of polymers. More particularly, the present invention relates to modifying a plastic surface by reacting a polysilicone compound to form a glass layer on the plastic surface.

### BACKGROUND OF THE INVENTION AND RELATED ART

Plastic devices have become ubiquitous in the medical field. Some devices are used only once, and then disposed, such as catheters or syringes. Others are sterilized and reused, such as surgical tools. Yet other devices are implanted into the human body, such as heart valves, artificial joints, lenses, and the like. While plastic materials have many aspects that make their use advantageous in a wide variety of technical fields, often, special surface properties are desired which can be difficult to achieve with plastic materials. For example, plastic medical devices are often required to provide a hydrophilic, hydrophobic, lubricious, or other special surface property. Unfortunately, polymers are generally inert, low surface energy materials and thus do not react with or adhere well to other materials. This makes it difficult to modify the surface of the polymer or to bond polymers to other materials. Furthermore, for implantable medical devices, it is often important that surfaces exposed to the body are biocompatible. This can require affixing various materials to the surface or otherwise modifying the structure of the surface.

Plasma surface modification is one known technique for modifying the surface of a polymer part. The technique is carried out in a partial vacuum where a gas is excited into a plasma. Excited species in the gas react with the surface layers of the polymer, leaving the bulk of the part unchanged. Various surface properties, such as hardness, reactivity, and biocompatibility can be obtained. Plasma surface modification, however, has several disadvantages, including the expense, necessary equipment, degradation of surface properties over time, and difficulty in controlling the chemical reactions that occur. Moreover, it is difficult to generate a plasma in a small area, such as inside a small-diameter tube. Hence, what is needed is an improved method of modifying a plastic surface.

### SUMMARY OF THE INVENTION

The present invention includes a method of modifying a plastic surface. One step of the method is placing a polysilicone compound in contact with the surface portion of a plastic part. Another step of the method is modifying the polysilicone compound using a chemical reaction to interactively form a glass layer containing silicon dioxide on the surface portion. The method also includes modifying the glass layer with a second process to create a desired surface property.

### BRIEF DESCRIPTION OF THE DRAWINGS

The present invention will become more fully apparent from the following description and appended claims, taken in conjunction with the accompanying drawings. Understanding that these drawings merely depict exemplary embodiments of the present invention they are, therefore, not to be considered limiting of its scope. It will be readily appreciated that the parts of the present invention, as generally described and illustrated in the figures herein, can be arranged and designed in a wide variety of different configurations. Nonetheless, the invention will be described and explained with additional specificity and detail through the use of the accompanying drawings in which:

FIG. 1 illustrates a perspective view of a part having a plastic surface undergoing a method of treatment in accordance with an embodiment of the present invention; and

FIG. 2 illustrates a perspective view of a plastic tube being treated in accordance with an embodiment of the present invention.

### DETAILED DESCRIPTION OF EXEMPLARY EMBODIMENTS

The following detailed description of exemplary embodiments of the invention makes reference to the accompanying drawings, which form a part hereof and in which are shown, by way of illustration, exemplary embodiments in which the invention may be practiced. While these exemplary embodiments are described in sufficient detail to enable those skilled in the art practice the invention, it should be understood that other embodiments may be realized and that various changes to the invention may be made without departing from the spirit and scope of the present invention. Thus, the following more detailed description of the embodiments of the present invention is not intended to limit the scope of the invention, as claimed, but is presented for purposes of illustration only and not limitation to describe the features and characteristics of the present invention and to sufficiently enable one skilled in the art to practice the invention. Accordingly, the scope of the present invention is to be defined solely by the appended claims.

It must be noted that, as used in this specification and the appended claims, the singular forms “a,” “an,” and “the” include plural referents unless the context clearly dictates otherwise. Thus, for example, reference to “a polysilicone compound” includes one or more of such materials, reference to “an interior surface” includes reference to one or more of such surfaces, and reference to “a plastic part” includes reference to one or more of such parts.

In describing and claiming the present invention, the following terminology will be used in accordance with the definitions set forth below.

As used herein, a “part” is any object of any shape or size that is to be modified in accordance with the present invention. Although the part may be entirely made of plastic, it will be appreciated that this is not required. For example, the part may be an assembly formed of several different materials which include at least one plastic surface.

As used herein, “polysilicone compound” is a polymerized siloxane compound having the empirical formula [R₂SiO]ₙ, where R is an organic group and n is a positive integer.

The following detailed description and exemplary embodiments of the invention will be best understood by reference to the accompanying drawings, wherein the elements and features of the invention are designated by numerals throughout.

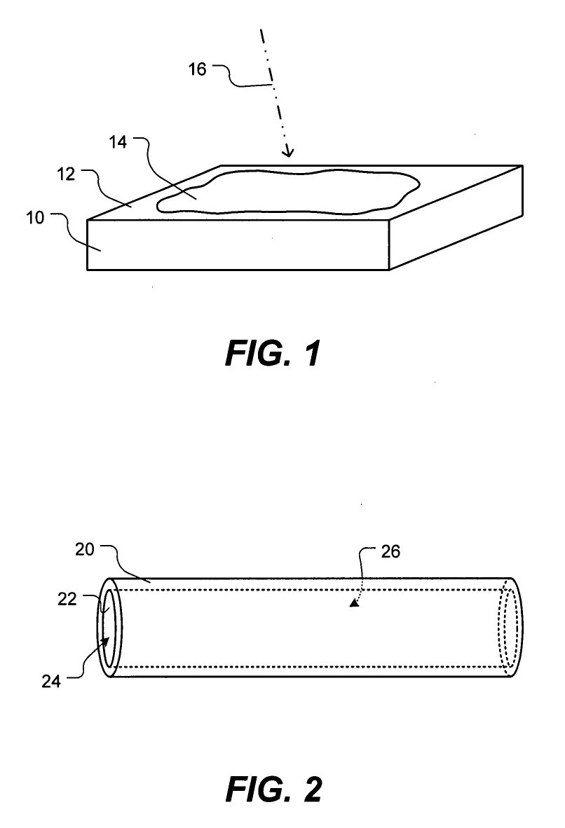

In accordance with an embodiment of the present invention, a method for modifying a plastic surface of a part will now be described with reference to FIG. 1. The part 10 can be, for example, a medical device or component. One step of the method includes placing a polysilicone compound 14 in contact with a plastic surface portion 12 of the part. For example, dimethylsiloxane can be used. The polysilicone compound can be placed in contact with the surface portion by spin coating, dip coating, roll coating, capillary action, spraying, filling, brush coating, and combinations thereof as will occur to one of skill in the art.

Another step of the method includes modifying the polysilicone compound using a chemical reaction to interactively form a silicon dioxide containing glass layer on the surface portion. Modifying the polysilicone compound can be accomplished by initiating the chemical reaction with ultraviolet radiation, such as by illumination 16 from a laser. For example, dimethylsiloxane silicone oil can be photo-oxidized to form SiO₂ glass by exposure to a deep ultraviolet light source (e.g., wavelength of 100-200 nm). Oxygen in the silicone oil and oxygen adsorbed onto the plastic surface are photoexcited and react with the silicone oil to form a glass layer on the plastic surface. Accordingly, the glass layer can be bonded to oxygen present in the plastic surface, providing strong adhesion between the glass layer and the plastic surface. The methyl group of the silicone oil is dissociated and reacts with active oxygen to form CO₂ or H₂O, which may be subsequently photodissociated to provide active oxygen for the reaction. Cleaning the plastic surface before and after reacting the polysilicone compound can also be included, for example, to remove excess unreacted compound from the part.

The method can also include modifying the glass layer with a second process to create a desired surface property. Since the glass layer has different properties than the plastic surface, forming the glass layer activates the plastic surface for sub-reactive processes that may not have been possible on the plastic surface directly.

For example, the second process can include depositing a desired coating on the glass layer. The second process can result in creating a hydrophobic, hydrophilic, lubricious, reactive, inert, rough, or biocompatible surface.

It will be appreciated that glass is inherently resistant to water. Accordingly, as a particularly detailed example, the method can be performed on a water-soluble plastic. By coating the water-soluble plastic surface with a glass layer, chemical reactions that would be incompatible with the water-soluble plastic can be performed on the glass layer.

A part processed according to the method can be particularly advantageous in the medical field. Certain polymers are desirable materials for implantable medical devices due to high strength, low weight, or high resiliency. Biocompatibility of polymers, however, is a complex issue, and there is a perceived need for better surface coating technologies. By introducing an intermediate glass layer, a new field of coatings, previously only applied to glass, can be applied to a plastic surface of a part. For example, various hemocompatible coatings are known which can be applied on glass. Other techniques can modify the intermediate glass layer to impart properties comparable to biological matter, such as cortical bone, for improved implant stability. Accordingly, a part processed according to the method described above may prove advantageous for use as a medical device.

Another particularly detailed exemplary embodiment of the present invention will now be described with reference to FIG. 2. A method of modifying a plastic surface can include providing a plastic part in the form of a tube 20 having an interior surface 22 and an opening 24. The method can include filling at least a portion of the interior 26 of the tube with a polysilicone compound. The method can also include modifying the polysilicone compound using a chemical reaction to form a glass layer containing silicon dioxide on the interior surface.

For example, as described above, modifying the polysilicone compound can be accomplished by initiating the chemical reaction with a source of ultraviolet radiation, such as a laser. Ultraviolet light can be shined either through the tube or into the end of the tube.

For example, ultraviolet light can be directed into the opening of the tube so that the interior surface of the tube provides a waveguide effect to contain the ultraviolet radiation substantially inside the tube. More particularly, by selecting a polysilicone compound having a refractive index lower than that of the material of the tube, the tube will behave similarly to an optical fiber, keeping most of the ultraviolet radiation within the interior of the tube.

The method thus solves the previously difficult problem of depositing a glass layer on the interior surface of a tube. The glass coating deposited on the interior of the tubing can serve to passivate the interior of the tube. This can enhance the utility of the tube, for example, in applications such as the medical field. As mentioned above, glass coatings also have a number of advantages. For example, a second process can be performed to modify the glass layer to create a desired surface property such as creating a hydrophobic, hydrophilic, lubricious, reactive, inert, rough, or biocompatible surface.

Summarizing and reiterating to some extent, it will now be appreciated that embodiments of the present invention provide a method for providing a variety of surface treatments to a plastic surface by forming an intermediate glass layer on the plastic surface. Treatment processes which cannot be performed directly on the plastic or which perform poorly on the plastic may be used to modify the glass layer surface. Parts treated according to the disclosed techniques may prove particularly suitable for medical applications.

The foregoing detailed description describes the invention with reference to specific exemplary embodiments. However, it will be appreciated that various modifications and changes can be made without departing from the scope of the present invention as set forth in the appended claims. The detailed description and accompanying drawings are to be regarded as merely illustrative, rather than as restrictive, and all such modifications or changes, if any, are intended to fall within the scope of the present invention as described and set forth herein.

More specifically, while illustrative exemplary embodiments of the invention have been described herein, the present invention is not limited to these embodiments, but includes any and all embodiments having modifications, omissions, combinations (e.g., of aspects across various embodiments), adaptations and/or alterations as would be appreciated by those in the art based on the foregoing detailed description. The limitations in the claims are to be interpreted broadly based the language employed in the claims and not limited to examples described in the foregoing detailed description or during the prosecution of the application, which examples are to be construed as non-exclusive. For example, in the present disclosure, the term “preferably” is non-exclusive where it is intended to mean “preferably, but not limited to.” Any steps recited in any method or process claims may be executed in any order and are not limited to the order presented in the claims. Means-plus-function or step-plus-function limitations will only be employed where for a specific claim limitation all of the following conditions are present: a) “means for” or “step for” is expressly recited in that limitation; b) a corresponding function is expressly recited in that limitation; and c) structure, material or acts that support that function are described within the specification. Accordingly, the scope of the invention should be determined solely by the appended claims and their legal equivalents, rather than by the descriptions and examples given above.

What is claimed is:

1. A method for modifying a plastic surface of a part, comprising:
a) placing a polysilicone compound in contact with at least a portion of the plastic surface of the part;
b) modifying the polysilicone compound using a chemical reaction to interactively form a glass layer containing silicon dioxide on the plastic surface portion; and
c) modifying the glass layer with a second process to create a desired surface property.

2. The method of claim 1, wherein the polysilicone is dimethylsiloxane.

3. The method of claim 1, wherein the step of modifying the polysilicone compound is accomplished by initiating the chemical reaction with ultraviolet radiation.

4. The method of claim 1, wherein the plastic surface portion includes a water-soluble plastic.

5. The method of claim 1, wherein the polysilicone compound is placed in contact with the plastic surface portion of the plastic part by spin coating, dip coating, roll coating, capillary action, spraying, filling, brush coating, and combinations thereof.

6. The method of claim 1, wherein the step of modifying the glass layer with a second process results in creating a hydrophobic surface.

7. The method of claim 1, wherein the step of modifying the glass layer with a second process results in creating a hydrophilic surface.

8. The method of claim 1, wherein the polysilicone compound is dimethylsiloxane.

9. The method of claim 1, further comprising the step of using the part in a medical device.

10. A method for modifying a plastic surface, comprising:
a) providing a plastic part in the form of a tube having an interior surface and an opening;
b) filling at least a portion of the tube with a polysilicone compound; and
c) modifying the polysilicone compound using a chemical reaction to form a glass layer containing silicon dioxide on the interior surface of the tube.

11. The method of claim 10, wherein the step of modifying the polysilicone compound is accomplished by initiating the chemical reaction with a source of ultraviolet radiation.

12. The method of claim 11, wherein initiating the chemical reaction comprises directing the source of ultraviolet radiation into the opening in the tube so that the interior surface of the tube provides a waveguide effect to contain the ultraviolet radiation substantially inside the tube.

13. The method of claim 12, wherein the polysilicone compound is substantially transparent to ultraviolet radiation and has a refractive index less than that of the interior surface of the tube

14. The method of claim 10, further comprising the step of modifying the glass layer with a second process to create a desired surface property.

15. The method of claim 14, wherein the step of modifying the glass layer with a second process results in creating a hydrophobic surface.

16. The method of claim 14, wherein the step of modifying the glass layer with a second process results in creating a hydrophilic surface.

17. The method of claim 10, further comprising the step of using the plastic part in a medical device.

18. A method for modifying a plastic surface of a part, comprising:
a) placing a polysilicone compound in contact with at least a portion of a plastic surface of the part;
b) modifying the polysilicone compound using a chemical reaction to form a silicon dioxide containing glass layer bonded to oxygen present in the surface portion; and
c) modifying the glass layer with a second process to create a desired surface property.

19. The method of claim 18, wherein the step of modifying the glass layer with a second process results in a surface property selected from the group of surface properties consisting of hydrophobic, hydrophilic, lubricious, reactive, inert, rough, and biocompatible.
